(19) United States
(12) Patent Application Publication
(10) Pub. No.: US 2026/0009592 A1
(43) Pub. Date: Jan. 8, 2026

(54) LOOPED HEAT PIPE WITH DUAL DIAMETER

(71) Applicant: NIDEC CHAUN-CHOUNG TECHNOLOGY CORPORATION, NEW TAIPEI CITY (TW)

(72) Inventors: Chuan-Yu LEE, NEW TAIPEI CITY (TW); Chia-Ling CHIN, NEW TAIPEI CITY (TW); Jheng-Yan WANG, NEW TAIPEI CITY (TW)

(21) Appl. No.: 18/765,205

(22) Filed: Jul. 5, 2024

(51) Int. Cl. F28D 15/04

(52) U.S. Cl. CPC F28D 15/043

(57) ABSTRACT

A looped heat pipe includes a looped tube, a capillary structure, a stopper and a working fluid. The looped tube includes a first tube and a second tube with different diameters. The second tube sheathes the first tube to seal two ends of the first tube. The capillary structure is disposed on inner walls of the first tube and the second tube. The stopper is placed in the looped tube to block a section therein. The working fluid is contained in the looped tube. The working fluid is vaporized to be vapor to flow in the looped tube after heating, the vapor flow in a specific direction with blocking of the stopper, and then the vapor is cooled to flow along the capillary structure.

### TECHNICAL FIELD

The technical field relates to a heat pipe, and more particularly relates to a looped heat pipe.

### DESCRIPTION OF RELATED ART

Heat pipes have rapid temperature equalization and heat conduction properties and are now widely used in thermal conduction devices such as heat exchangers and heat sinks. The operation of a heat pipe involves the working fluid vaporizing in the tube after heating. The vapor is then cooled and condenses back into a liquid through heat exchange, thereby transferring heat through this circulation.

When the working liquid in the heat pipe vaporizes after heating, the flow direction in the tube may vary, leading to uneven temperature distribution. This may cause the heat pipe to overheat in some areas while remaining at a lower temperature in others. This affects its normal operation and decrease heat transfer efficiency. Additionally, the vapor may cause pressure loss during flow, which may increase when the flow direction changes. As a result, the performance and stability of the heat pipe are adversely affected.

In view of the above drawbacks, the inventor proposes this disclosure based on his expert knowledge and elaborate researches in order to solve the problems of the related art.

### SUMMARY OF THE DISCLOSURE

One object of this disclosure is to provide a looped heat pipe that directs the flow of vapor in the heat pipe consistently to effectively transfer heat, and to ensure the performance and stability of the heat pipe.

In order to achieve the object mentioned above, this disclosure provides a looped heat pipe including a looped tube, a capillary structure, a stopper and a working fluid. The looped tube includes a first tube and a second tube with different diameters. The second tube connects the first tube to seal two ends of the first tube. The capillary structure is disposed on inner walls of the first tube and the second tube. The stopper is placed in the looped tube to block a section thereof. The working fluid is disposed in the looped tube. The working fluid is vaporized to be a vapor to flow in the looped tube after being heated. The vapor flows in a specific direction with blocking of the stopper, and then the vapor is cooled back to the working fluid to flow along the capillary structure.

In one embodiment of this disclosure, the capillary structure is a plate made of braided metal wire.

In one embodiment of this disclosure, the capillary structure is distributed around part of inner wall of the looped tube.

In one embodiment of this disclosure, the capillary structure is distributed around entire inner walls of the looped tube.

In one embodiment of this disclosure, the stopper is a cylinder made by sintering powdered metal.

In one embodiment of this disclosure, the stopper is positioned in the first tube; one side of the stopper abuts against inner wall of the first tube, and another side of the stopper abuts against the capillary structure.

In one embodiment of this disclosure, the first tube is a straight pipe and includes a first pipe diameter, and the second tube is a U-shaped pipe and includes a second pipe diameter.

In one embodiment of this disclosure, the first tube and the second tube are joined in a tight fit manner.

In one embodiment of this disclosure, the looped heat pipe further includes a plurality of solder arranged at the junctions of the first tube and the second tube.

In one embodiment of this disclosure, the looped heat pipe further includes a degassing pipe attached to the looped tube.

Compared with the related art, the looped heat pipe of this disclosure includes a first tube and a second tube with different diameters. The capillary structure is disposed on the inner walls of the first tube and the second tube, and a stopper is positioned in the looped tube to obstruct a portion of the looped tube. Additionally, the working fluid is vaporized to be vapor after heating and flows through the looped tube. When the vapor encounters the stopper, the vapor is blocked and reverses its flow direction. Thus, the flow of vapor in the heat pipe is consistent with the arrangement of the stopper, and the vapor is cooled to flow along the capillary structure. This circulation enables the working fluid to efficiently dissipate heat generated by heating elements in both liquid and vapor phases, and that ensures the performance and stability of the heat pipe and achieves the purpose of dissipating heat from heating elements.

### BRIEF DESCRIPTION OF DRAWINGS

The features of the disclosure believed to be novel are set forth with particularity in the appended claims. The disclosure itself, however, may be best understood by reference to the following detailed description of the disclosure, which describes a number of exemplary embodiments of the disclosure, taken in conjunction with the accompanying drawings, in which:

FIG. 1 is a perspective schematic view of the looped heat pipe in this disclosure.

FIG. 2 is a cross-sectional view of the looped heat pipe in this disclosure.

FIG. 3 and FIG. 4 are cross-sectional views of the looped heat pipe from two side thereof in this disclosure.

FIG. 5 is an operation schematic view of the looped heat pipe in this disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

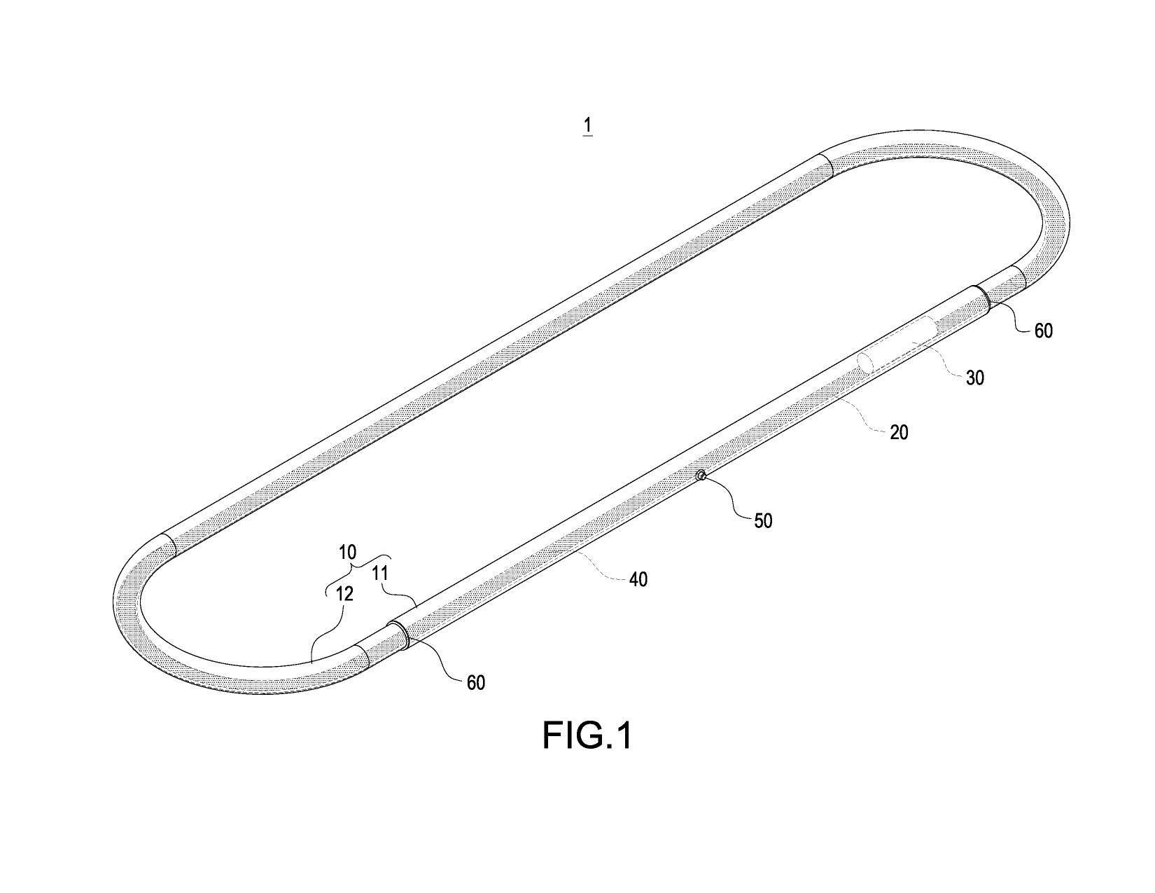

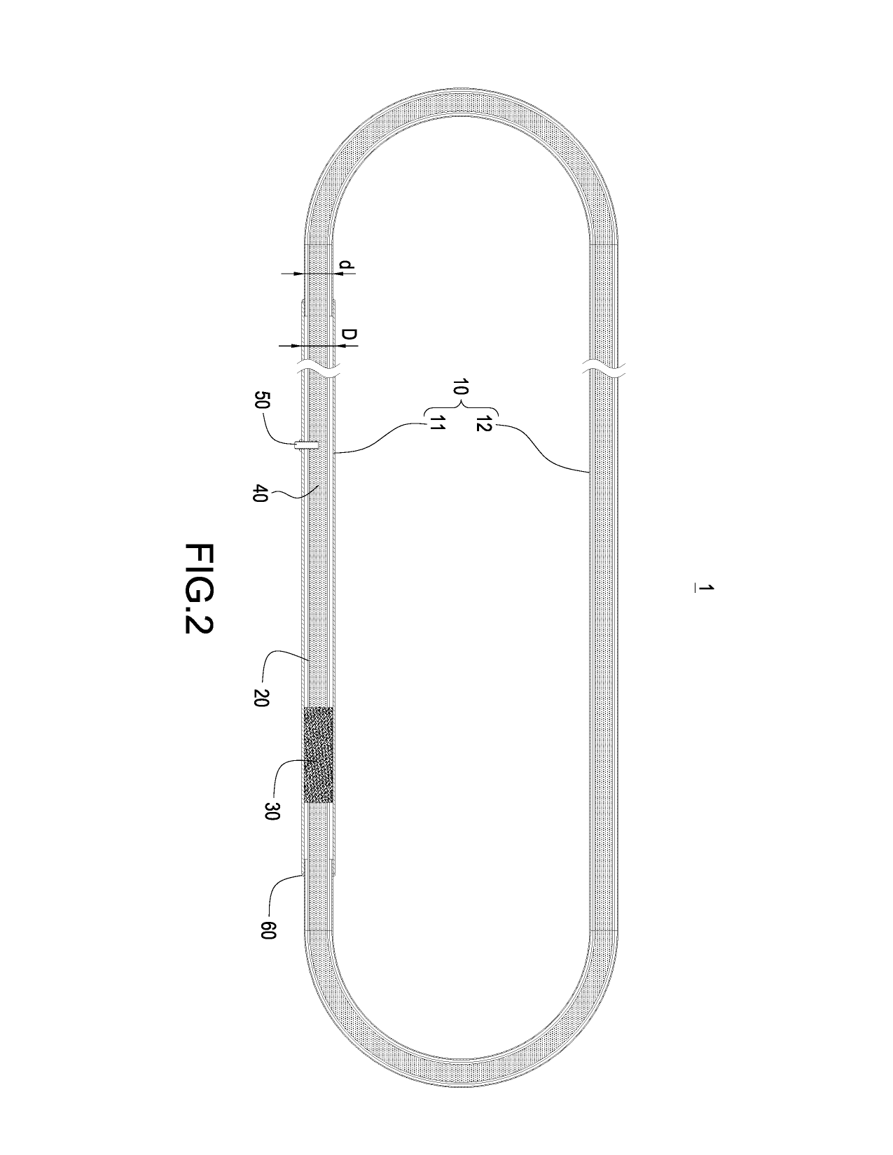

Please refer to FIG. 1 and FIG. 2, which depict a perspective schematic view and a cross-sectional view of the looped heat pipe in this disclosure. The looped heat pipe 1 with dual diameter of this disclosure includes a looped tube 10, a capillary structure 20, a stopper 30 and a working fluid 40. The capillary structure 20 and the stopper 30 are positioned in the looped tube 10, and the working fluid 40 is contained in the looped tube 10 to configure the looped heat pipe 1. More detailed descriptions of the structure of the looped heat pipe 1 are as follows.

In this embodiment, the looped tube 10 includes a first tube 11 and a second tube 12 with different diameters. The second tube 12 connects the first tube 11 to seal two ends of the first tube 11. The capillary structure 20 is disposed on both inner walls of the first tube 11 and the second tube 12. For example, the capillary structure 20 is a plate made of braided metal wire. It should be noted that the capillary structure 20 may be distributed around part of the inner walls of the looped tube 10, or it may be distributed around the entire inner walls of the looped tube 10. In this embodiment, the capillary structure 20 is distributed around the entire inner walls of the looped tube 10.

Moreover, the stopper 30 may be a cylinder or a fiber cylinder made by sintering powdered metal. The stopper 30 is inserted in the first tube 11. Additionally, the working fluid 40 is contained in the looped tube 10 and serves as a medium for heat transfer. Accordingly, the stopper 30 and the capillary structure 20 are inserted into one side of the first tube 11 to block the passage of vapor generated from the working fluid 40 after heating, thereby guiding the vapor flow. It is worth noting that the sintering mold of the stopper 30 may be made by inserting the capillary structure 20 and the mandrel into the first tube 11 to produce a semi-finished product, which is then sintered. Subsequently, the stopper 30 is inserted into either the first tube 11 or the second tube 12.

Furthermore, the looped heat pipe 1 also includes a degassing pipe 50 attached to the looped tube 10 to remove gas from inside the looped tube 10 and create a vacuum.

In this embodiment, the looped heat pipe 1 further includes a plurality of solder 60 arranged at the junctions of the first tube 11 and the second tube 12 to combine and secure them.

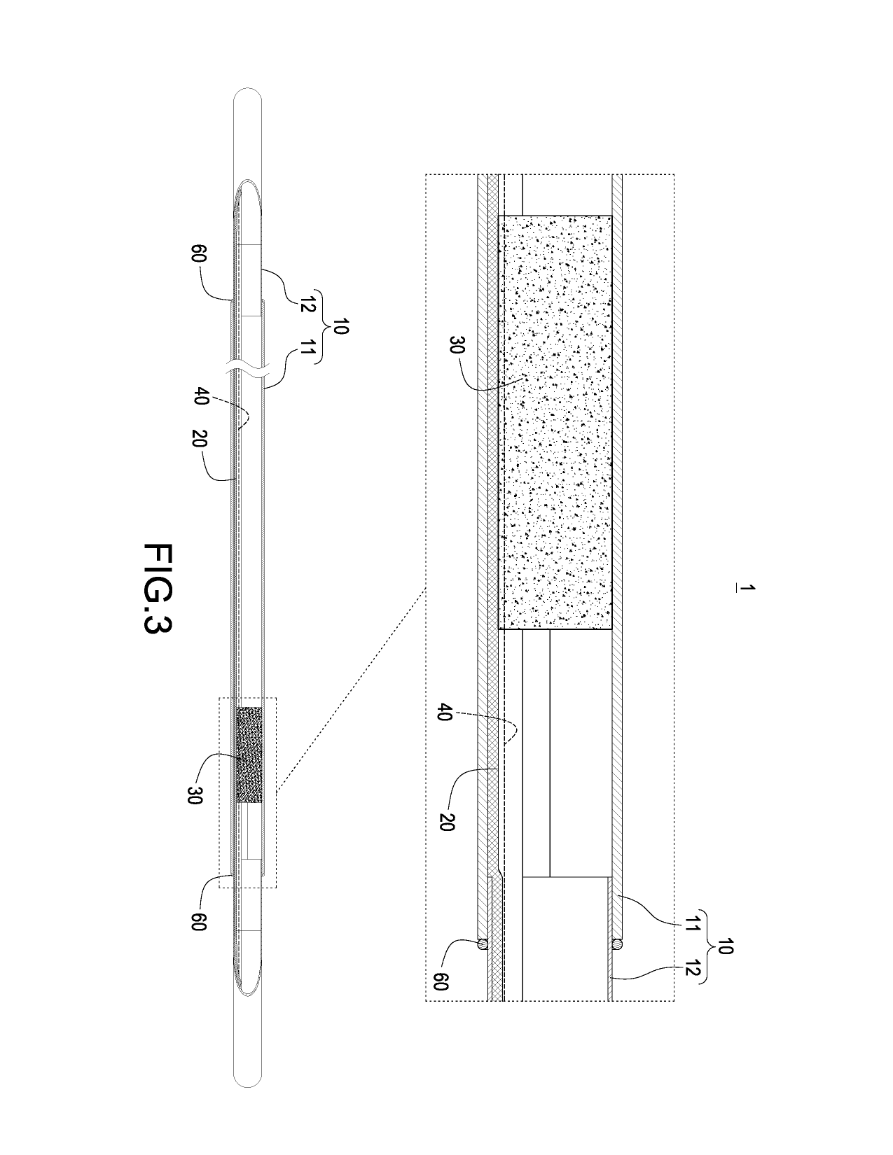

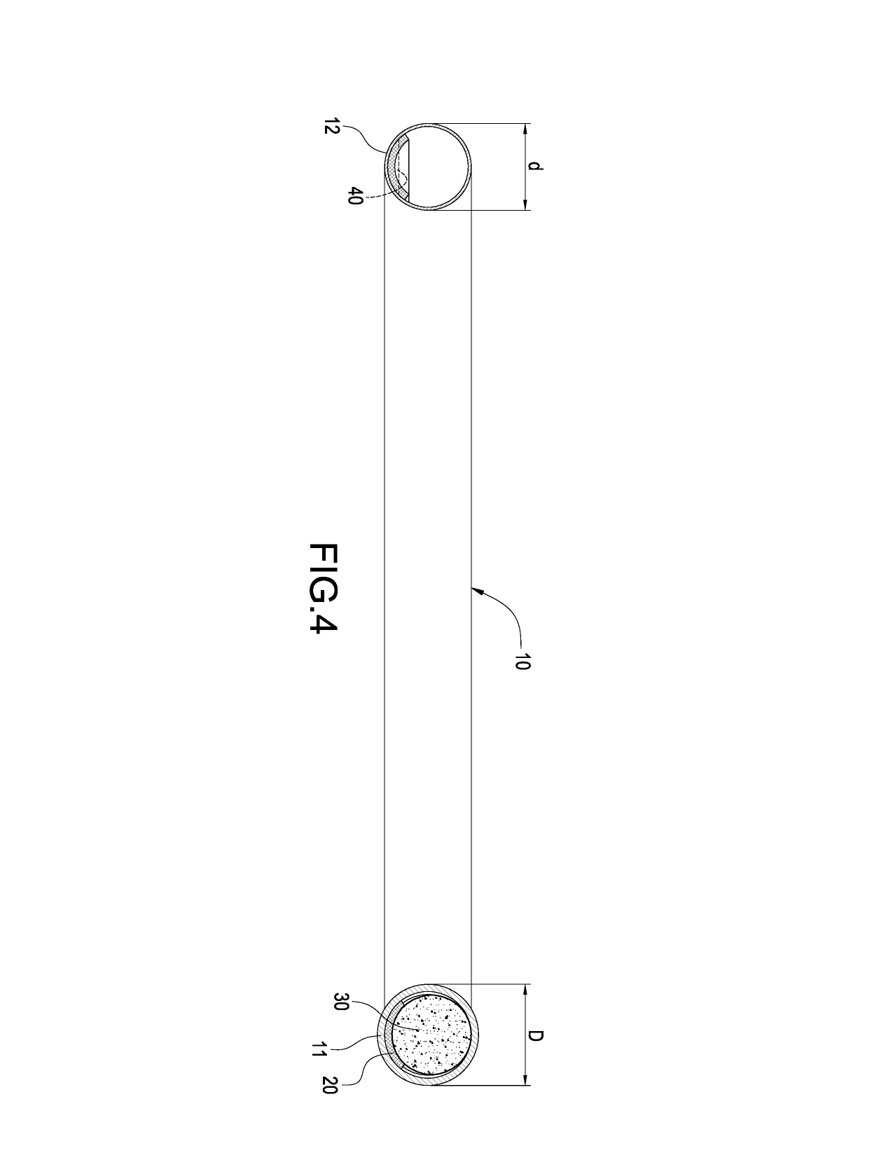

Please further refer to FIG. 3 and FIG. 4, which depict cross-sectional views of the looped heat pipe from two side thereof in this disclosure. The looped tube 10 of this disclosure includes the first tube 11 with a first pipe diameter D and a second pipe body 12 with a second pipe diameter d. In this embodiment, the first tube 11 is a straight pipe, and the second tube 12 is a U-shaped pipe, but this is not limited thereto. Additionally, the first pipe diameter D is slightly larger than the second pipe diameter d. In some embodiments, the first pipe diameter D and the second pipe diameter d are of different sizes. For example, the first pipe diameter D may be larger than the second pipe diameter d to increase the contact area with the heating element. Alternatively, the first pipe diameter D may be smaller than the second pipe diameter d.

Furthermore, in this disclosure, one side of the stopper 30 abuts against the inner wall of the first tube 11, and another side of the stopper 30 abuts against the capillary structure 20. Additionally, the stopper 30 and the capillary structure 20 are inserted into one side of the first tube 11. This arrangement of the stopper 30 guides the vapor flow in the looped tube 10.

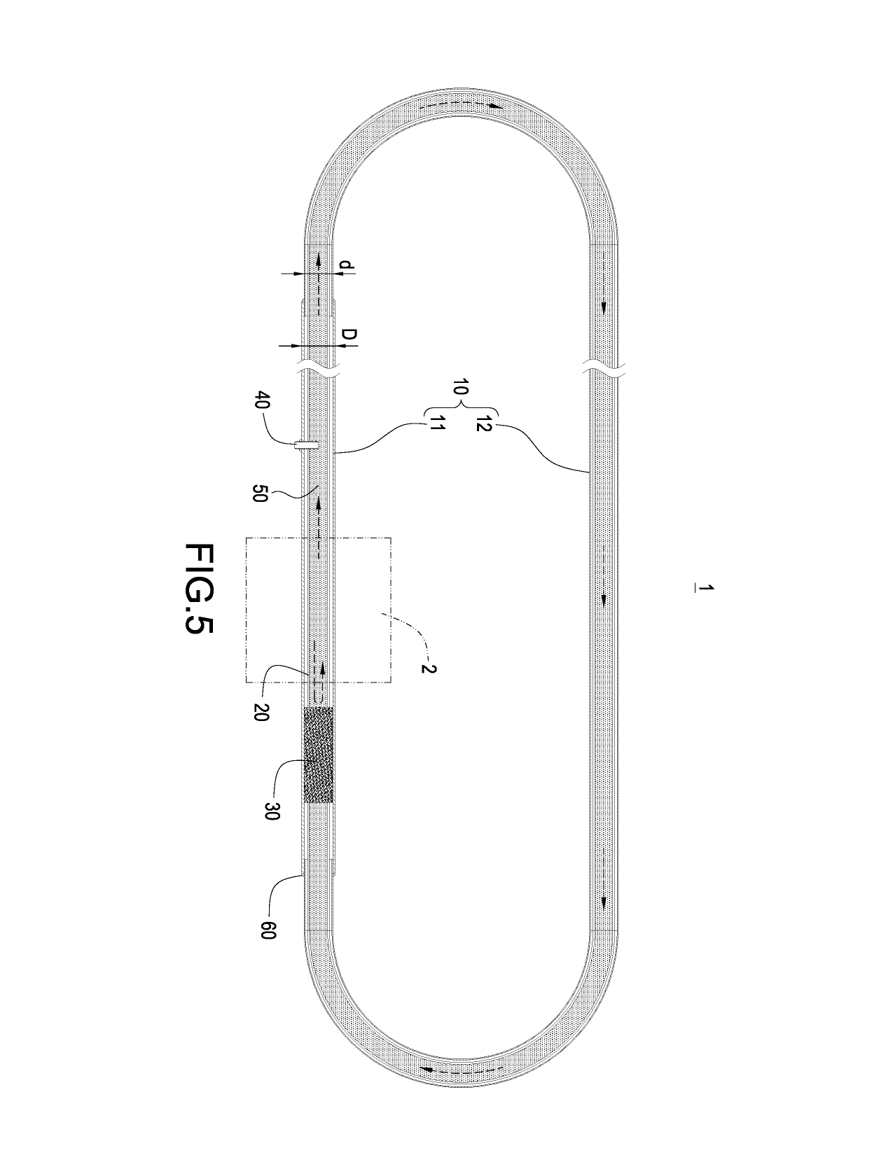

Please further refer to FIG. 5, which depict an operation schematic view of the looped heat pipe in this disclosure. The looped heat pipe 1 in this disclosure is used to dissipate heat of a heating element 2. In some embodiments, the working fluid 40 is vaporized to be vapor after absorbing heat and then the vapor flows through the looped tube 10. When the vapor encounters the stopper 30 in the looped tube 10, it is blocked and reverses its flow direction. This arrangement ensures that the vapor flows in a predetermined direction, guided by the placement of the stopper 30, allowing for consistent vapor flow in the heat pipe. After cooling, the vapor is back to the working fluid to flow along the capillary structure 20 and returns to the location of the heating element. This circulation allows the working fluid 40 to transition between liquid and gas phases, thereby effectively dissipating heat from the heating element 2.

While this disclosure has been described by means of specific embodiments, numerous modifications and variations could be made thereto by those skilled in the art without departing from the scope and spirit of this disclosure set forth in the claims.

What is claimed is:

1. A looped heat pipe, comprising:
a looped tube, comprising a first tube and a second tube with different diameters, the second tube connecting the first tube to seal two ends of the first tube;
a capillary structure, disposed on inner wall of the first tube and inner wall of the second tube;
a stopper, placed in the looped tube to block a section therein; and
a working fluid, contained in the looped tube;
wherein the working fluid is vaporized to be a vapor to flow in the looped tube after being heated, the vapor flows in a specific direction with blocking of the stopper, and then the vapor is cooled back to the working fluid to flow along the capillary structure.

2. The looped heat pipe according to claim 1, wherein the capillary structure is a plate made of braided metal wire.

3. The looped heat pipe according to claim 1, wherein the capillary structure is distributed around part of inner wall of the looped tube.

4. The looped heat pipe according to claim 1, wherein the capillary structure is distributed around entire inner wall of the looped tube.

5. The looped heat pipe according to claim 1, wherein the stopper is a cylinder made by sintering powdered metal.

6. The looped heat pipe according to claim 1, wherein the stopper is positioned in the first tube; one side of the stopper abuts against inner wall of the first tube, and another side of the stopper abuts against the capillary structure.

7. The looped heat pipe according to claim 1, wherein the first tube is a straight pipe and comprises a first pipe diameter, and the second tube is a U-shaped pipe and comprises a second pipe diameter.

8. The looped heat pipe according to claim 1, wherein the first tube and the second tube are joined in a tight fit manner.

9. The looped heat pipe according to claim 1, further comprising a plurality of solder arranged at a junction of the first tube and the second tube.

10. The looped heat pipe according to claim 1, further comprising a degassing pipe attached to the looped tube.
